(19) United States
(12) Patent Application Publication
(10) Pub. No.: US 2018/0108764 A1
(43) Pub. Date: Apr. 19, 2018

(54) SEMICONDUCTOR DEVICE

(71) Applicant: FUJI ELECTRIC CO., LTD., Kawasaki-shi (JP)

(72) Inventor: Kenichi ISHII, Matsumoto-city (JP)

(73) Assignee: FUJI ELECTRIC CO., LTD., Kawasaki-shi (JP)

(21) Appl. No.: 15/692,582

(22) Filed: Aug. 31, 2017

(30) Foreign Application Priority Data
Oct. 17, 2016 (JP) 2016-203501

(51) Int. Cl. H01L 29/739; H01L 29/866; H01L 29/10; H01L 27/02

(52) U.S. Cl. CPC H01L 29/7393; H01L 27/0255; H01L 29/1095; H01L 29/866

(57) ABSTRACT

In an active region, a MOS gate of an IGBT is provided on a front surface side of a semiconductor substrate. In an edge termination region, a Zener diode is provided on the front surface of the semiconductor substrate, via a field oxide film. The semiconductor substrate is one of semiconductor chips formed by cutting, into individual chips, a diffused wafer that includes a p⁺-type diffusion layer formed by diffusing boron in a surface layer of one main surface of an n⁻-type starting wafer. An outermost p⁺-type region of the IGBT faces the Zener diode across a field oxide film in the depth direction. The thickness of the p⁺-type diffusion layer is 100 μm or more. The thickness of the n⁻-type drift region is 100 μm or more. The thickness of the semiconductor substrate is 200 μm or more.

### CROSS REFERENCE TO RELATED APPLICATIONS

This application is based upon and claims the benefit of priority of the prior Japanese Patent Application No. 2016-203501, filed on Oct. 17, 2016, the entire contents of which are incorporated herein by reference.

### BACKGROUND OF THE INVENTION

### 1. Field of the Invention

Embodiments of the invention relate to a semiconductor device.

### 2. Description of the Related Art

A semiconductor device that controls low voltage current supplied to a primary coil of an ignition coil according to a signal of an engine control unit (ECU) (an igniter) serves as a constituent unit of an internal combustion engine ignition that ignites and combusts an air-fuel mixture introduced into a combustion chamber of an engine used in an automobile or the like. Use of an insulated gate bipolar transistor (IGBT) for this igniter is currently the mainstream because of the ease of gate control thereof.

FIG. 12 is a circuit diagram of a circuit configuration of an ordinary internal combustion engine ignition. FIG. 13 is a circuit diagram of a circuit configuration of an ordinary igniter. The internal combustion engine ignition 100 depicted in FIG. 12 includes an igniter 101, an ignition coil 102, and a spark plug 103. The igniter 101 includes an IGBT 111 as a switch that causes low voltage current flowing through a primary coil of an ignition coil to flow or stop, and a control circuit/protective circuit 112 that controls the IGBT 111. The IGBT 111 is a switch that causes the low voltage current flowing from a battery (14 V) through the primary coil of the ignition coil 102 to flow or stop according to an electrical signal from the ECU 104.

A collector terminal C of the IGBT 111 (a high potential side terminal of the igniter 101) is connected to the primary coil of the ignition coil 102. An emitter terminal E of the IGBT 111 (a low potential side terminal of the igniter 101) is grounded (the ground). A gate terminal G of the IGBT 111 is connected to a gate driving circuit of the ECU 104. The ignition coil 102 increases the voltage of the low voltage current supplied to the primary coil using a mutual induction action to generate high voltage current corresponding to the number of turns of the secondary coil. The secondary coil of the ignition coil 102 is connected to the spark plug 103.

In the internal combustion engine ignition 100, the IGBT 111 is turned on according to an on-signal from the ECU 104 and as a result the low voltage current flows from the battery through the primary coil of the ignition coil 102. On the other hand, the IGBT 111 is turned off by an off-signal from the ECU 104 and the potential at the collector terminal C increases. As a result, the current flowing through the primary coil of the ignition coil 102 is blocked and the voltage at the primary coil increases. Thus, a high voltage current is generated through the secondary coil of the ignition coil 102 and discharge occurs in the gap of the spark plug 103, firing the engine.

A current control circuit (not depicted), an overcurrent protective circuit 112a, an overheat detection circuit and a soft-off circuit 112b, a waveform shaping circuit 112c, a timer (not depicted), an abnormality detection circuit (not depicted), and the like are known as the control circuit/protective circuit 112 of the igniter 101 (FIG. 13). The current control circuit controls the gate voltage of the IGBT 111 such that the low voltage current flowing through the primary coil of the ignition coil 102 has a predetermined current value. The overcurrent protective circuit 112a instantaneously blocks the current flowing through the IGBT 111 independent of the control signal from the ECU 104 in an abnormal state where an overcurrent flows through the IGBT 111.

The soft-off circuit suppresses increases of the high voltage current generated by the secondary coil of the ignition coil 102 to an extent that no discharge occurs in the gap of the spark plug 103 in the combustion chamber of the engine. The waveform shaping circuit 112c limits the voltage applied between the collector and the gate of the IGBT 111. The overheat detection circuit measures the temperature of the semiconductor chip to detect an abnormality such as overheating. The timer measures the on-time period of the IGBT 111. The abnormality detection circuit measures the value of the current flowing through the IGBT 111 and the value of voltage applied between the collector and the emitter of the IGBT 111 to detect an abnormal state.

A cross-sectional structure of main portions of the igniter 101 will be described. FIG. 14 is a cross-sectional view of the structure of main portions of the conventional igniter. FIG. 14 depicts the vertical IGBT 111, and a horizontal metal oxide semiconductor field effect transistor (MOSFET) 112d constituting the control circuit/protective circuit 112. As depicted in FIG. 14, a semiconductor substrate (a semiconductor chip) 120 includes semiconductor layers to be an n⁺-type buffer region 122 and an n⁻-type drift region 123 that are sequentially stacked on each other on a p⁺-type starting substrate 121 to be a p⁺-type collector region of the IGBT 111.

A p-type base region 124 is selectively provided in the surface layer of the front surface of the semiconductor substrate 120. An n⁺-type emitter region 125 is selectively provided inside the p-type base region 124. A p⁺-type region 126 penetrating the p-type base region 124 to reach the n⁻-type drift region 123 is provided. The p⁺-type region 126 functions as a p⁺-type contact region. A gate electrode 127 is provided via the gate insulating film on the surface of the portion between the n⁻-type drift region 123 and the n⁺-type emitter region 125, of the p-type base region 124. The p-type base region 124, the n⁺-type emitter region 125, the p⁺-type region 126, and the gate electrode 127 constitute a MOS gate of the IGBT 111.

The p-type base region 124 also acts as a back gate of the MOSFET 112d. An n⁺-type source region 128 and an n⁺-type drain region 129 are selectively provided inside the p-type base region 124. A gate electrode 130 is provided via the gate insulating film on the surface of the portion of the p-type base region 124 between the n⁺-type source region 128 and the n⁺-type drain region 129. The p-type base region 124, the n⁺-type source region 128, the n⁺-type drain region 129, and the gate electrode 130 constitute a MOS gate of the MOSFET 112d. Reference numerals “131” to “134” respectively denote an emitter electrode, a collector electrode, a source electrode, and a drain electrode.

In a device proposed as an IGBT applicable to an igniter of an automobile, only cells located near an emitter pad having a high current concentration have an intermittent emitter structure and the intermittent emitter structure is applied near the emitter pad having the largest reduction of the latch-up capability (see, e.g., Japanese Laid-Open Patent Publication No. H10-093084). The intermittent emitter structure refers to a structure in which the emitter regions are cyclically provided at constant intervals in a direction along the MOS gate of the planar gate structure. Japanese Laid-Open Patent Publication No. H10-093084 discloses a so-called non-punch-through (NPT) IGBT having a p⁺-type collector region and the n⁻-type drift region provided adjacent to each other.

A device including a Zener diode arranged between the collector and the gate of an IGBT so that the gate side thereof is the anode side, has been proposed as another IGBT applicable to an igniter for an automobile (see, e.g., Japanese Laid-Open Patent Publication No. 2009-130096 (Paragraph 0004, FIG. 4)). In Japanese Laid-Open Patent Publication No. 2009-130096, the potential of the collector side becomes significantly low relative to that of the emitter side (the ground potential) when the IGBT is turned off from an on state, and an excessive surge voltage generated at the collector terminal of the IGBT is thereby clamped by the Zener diode to protect the IGBT from the surge voltage.

Igniters are conventionally known that are of a one-chip type having an IGBT and a control circuit/protective circuit arranged on a single semiconductor chip and of a multi-chip type having an IGBT and a control circuit/protective circuit each constituted by a semiconductor chip different from each other. A device having an IGBT and a Zener diode arranged on a single semiconductor substrate has been proposed as a one-chip type igniter having the IGBT and the protective circuit arranged on a single semiconductor substrate (the semiconductor chip) (see, e.g., Japanese Laid-Open Patent Publication No. H08-088354, Japanese Patent Publication No. 5194359, and International Patent Publication WO 2014/142331). In Japanese Laid-Open Patent Publication No. H08-088354, Japanese Patent Publication No. 5194359, and International Patent Publication WO 2014/142331, the Zener diode is arranged on the semiconductor substrate through an insulating film.

### SUMMARY OF THE INVENTION

According to one aspect of the present invention, a semiconductor device includes a semiconductor element including: a first semiconductor layer of a first conductivity type; a first semiconductor region of a second conductivity type selectively provided in a surface layer of the first semiconductor layer; a second semiconductor region of the first conductivity type selectively provided in the first semiconductor region; a third semiconductor region of the second conductivity type selectively provided in the first semiconductor region, the third semiconductor region having an impurity concentration higher than that of the first semiconductor region; a gate insulating film in contact with a region of the first semiconductor region between the first semiconductor layer and the second semiconductor region; a gate electrode facing the first semiconductor region across the gate insulating film; a second semiconductor layer of the second conductivity type provided on a first surface of the first semiconductor layer opposite a second surface of the first semiconductor layer on which the first semiconductor region is provided; a first electrode in contact with the second semiconductor region and the third semiconductor region; and a second electrode in contact with the second semiconductor layer of the second conductivity type. The semiconductor device further includes an oxide film provided on the second surface of the first semiconductor layer; and a diode provided on a surface of the oxide film. The diode has a first end electrically connected to the gate electrode and a second end electrically connected to the second electrode. A portion of the diode toward the first end faces the third semiconductor region across the oxide film.

In the semiconductor device, one third or more of the diode toward the first end faces the third semiconductor region across the oxide film in a depth direction.

In the semiconductor device, a thickness of the second semiconductor layer is 100 μm or more.

In the semiconductor device, a thickness of the first semiconductor layer is 100 μm or more.

In the semiconductor device, the second semiconductor layer is a diffusion layer provided in a surface layer of a semiconductor substrate of the first conductivity type, and the first semiconductor layer is a portion of the semiconductor substrate excluding the second semiconductor layer.

In the semiconductor device, a thickness of the semiconductor substrate is 200 μm or more.

In the semiconductor device, the semiconductor element is provided in an active region; the diode is provided in a termination region that surrounds a periphery of the active region; and the terminating region is arranged in a layout in which a portion having the diode provided therein protrudes toward the active region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of a semiconductor device according to an embodiment, taken along a cutting line X-X′ of FIG. 3;

FIG. 2 is an enlarged plan diagram of a Zener diode of FIG. 3;

FIG. 3 is a plan diagram of a planar layout of the semiconductor device according to the embodiment;

FIG. 4 is an explanatory diagram of a state of a depletion layer in an edge termination region of FIG. 1;

FIG. 5 is a circuit diagram of a surge voltage generating circuit that is used in a field decay test;

FIG. 6 is an explanatory diagram of a surge voltage application point of an internal combustion engine ignition in the field decay test;

FIG. 7 is a characteristics diagram of a surge voltage waveform applied in the field decay test;

FIGS. 8A and 8B are cross-sectional views of an example of a structure of a semiconductor wafer;

FIG. 9 is a cross-sectional view of another example of a structure of main portions of a conventional igniter;

FIG. 10 is a plan diagram of a planar layout of a Zener diode of FIG. 9;

FIG. 11 is a characteristics diagram of distribution of the potential difference between the Zener diode and a semiconductor substrate of FIG. 9;

FIG. 12 is a circuit diagram of a circuit configuration of an ordinary internal combustion engine ignition;

FIG. 13 is a circuit diagram of a circuit configuration of an ordinary igniter;

FIG. 14 is a cross-sectional view of a structure of main portions of a conventional igniter; and

FIG. 15 is a plan diagram of a planar layout of another example of a semiconductor device according to the embodiment.

### DETAILED DESCRIPTION OF THE INVENTION

Embodiments of a semiconductor device according to the present invention will be described in detail with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without +or −, and represents one example. In the description of the embodiments below and the accompanying drawings, main portions that are identical will be given the same reference numerals and will not be repeatedly described.

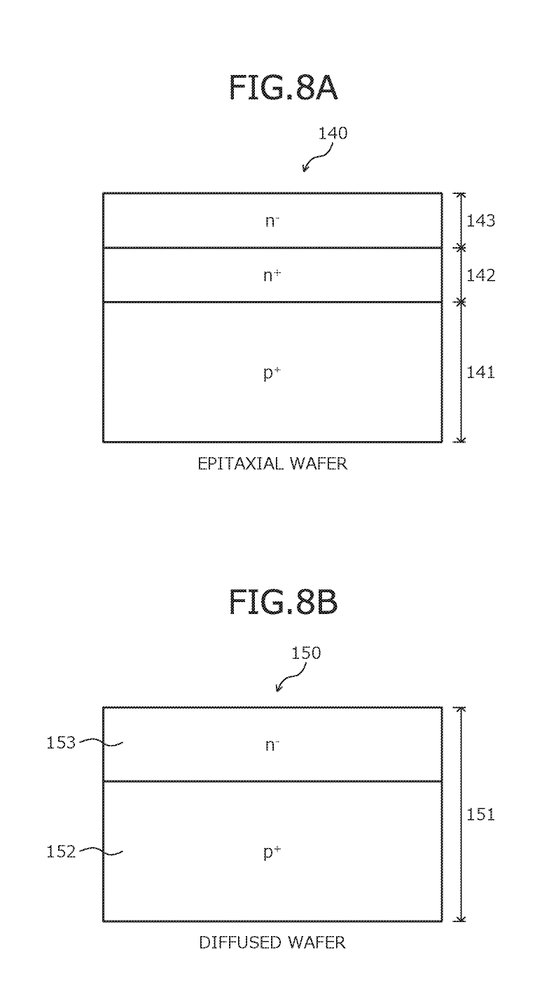

First, issues related to conventional techniques will be discussed. In addition to a switching function during normal operation, breakdown voltage capability between the collector and the emitter, and the like, breakdown tolerance against destruction in an abnormal state is further demanded of IGBTs. Breakdown voltage refers to a limit voltage at which element breakdown does not occur. An abnormal state refers to a case in which a steep surge voltage is generated between the collector and the emitter, or the like. With an igniter, for example, the breakdown voltage for normal operation may be 500 V while the breakdown voltage in a case of surge is 800 V. Conventionally, to obtain functions and performance demanded for normal operation and in an abnormal state, an epitaxial wafer 140 is used that is formed by sequentially forming by epitaxial growth on a starting wafer 141 forming a p⁺-type collector region (FIG. 8A), semiconductor layers 142 and 143 respectively forming an n⁺-type buffer region and an n⁻-type drift region. FIGS. 8A and 8B are cross-sectional views of an example of the structure of the semiconductor wafer.

However, the epitaxial wafer 140 is relatively expensive because of increased manufacturing steps. For an inverter use and the like, instead of the epitaxial wafer 140, an inexpensive floating zone (FZ) wafer (not depicted) is used that is produced using a FZ method. The FZ wafer includes one single layer of the n-type or the p-type. When, for example, an n-type FZ wafer is used in an igniter, a step of forming the p⁺-type collector region using ion implantation for the surface layer of the rear surface of the FZ wafer is necessary. During the assembling of the product, solder adheres to a side face of a chip (a cutting surface) when the semiconductor chip that is one of the chips formed by cutting the FZ wafer into individual chips is soldered to a circuit pattern (copper foil) on the insulated substrate.

The breakdown voltage of the chip side face is reduced by the damage caused thereto by the cutting. In addition, an end portion of a pn-junction between the p⁺-type collector region and the n⁻-type drift region exposed at the chip side face is a portion through which current mainly flows when a reverse voltage is applied to the IGBT, and functions as a product are lost resulting in the manufacturing of a defective product when the solder adheres to the end portion of the pn-junction. Because the thickness of the p⁺-type collector region formed using ion implantation in the rear surface of the FZ wafer is several μm, the solder tends to adhere to the end portion of the pn-junction between the p⁺-type collector region and the n⁻-type drift region exposed at the chip side face. Therefore, a structure is necessary to prevent adverse effects caused by the adhesion of the solder to the chip side face during the manufacture of the product.

Examples of a method to prevent adverse effects caused by the solder include formation of a p-type region at the chip side face, spanning from the chip front surface to reach the rear surface, while an ion implantation step to form the p-type region in the chip side face, and the like are also necessary. When a FZ wafer is used in an igniter as described, the cost increases due to the increased number of the manufacturing steps, reducing the advantages of using an inexpensive FZ wafer. Countermeasures to solve this problem, the include use of a diffused wafer (DW) 150 that includes a p⁺-type diffusion layer 152 formed by diffusing, for example, boron (B) in the surface layer of one main surface of an n⁻-type starting wafer 151 (FIG. 8B).

With the diffusion wafer 150, the thickness of the p⁺-type diffusion layer 152 to become the p⁺-type collector region may be ensured to be about 100 μm whereby adverse effects caused by the solder adhering to the chip side face may be prevented as compared to the FZ wafer. The diffused wafer 150 is inexpensive compared to the epitaxial wafer 140. However, in the diffused wafer 150 during the manufacture of the diffused wafer 150, a two-stage impurity concentration profile of the same conductivity type (the impurity concentration profile of the n⁻-type drift region and the n⁺-type buffer region) is impossible to form. For example, according to a method proposed as the fabrication method for a diffused wafer, a central portion of a silicon (Si) wafer having a diffusion layer formed in both main surfaces thereof is cut, obtaining a diffused wafer that includes a diffusion layer only in one main surface (see, e.g., Japanese Laid-Open Patent Publication No. H3-038035).

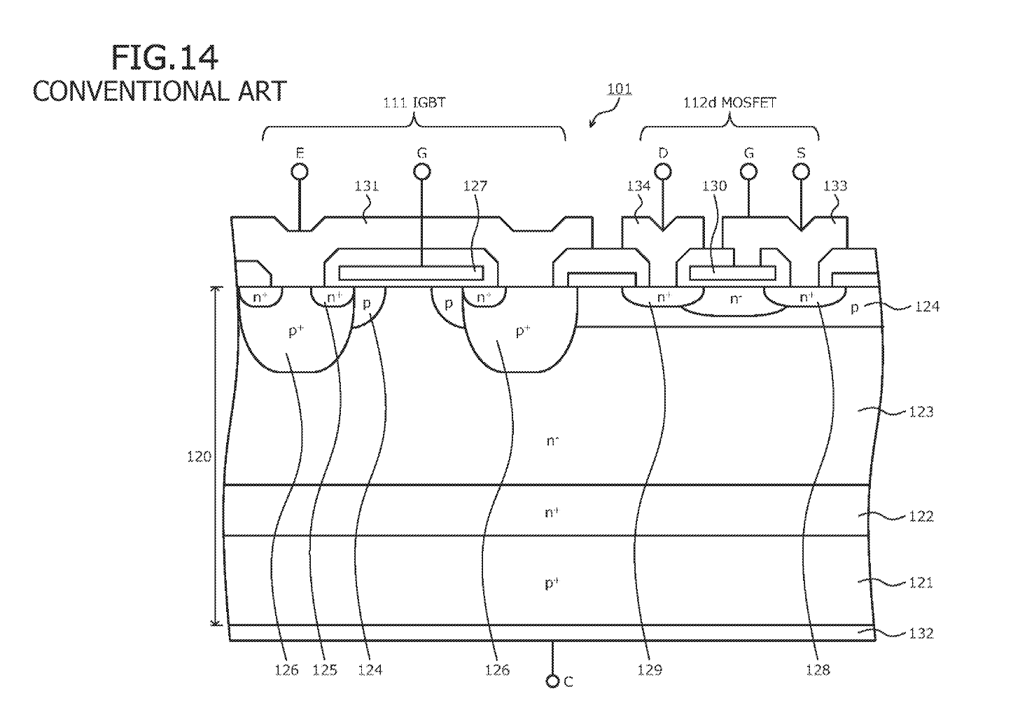

Therefore, the breakdown voltage has to be secured by increasing the thickness of the n⁻-type drift region 153 by an amount corresponding to the n⁺-type buffer region not provided or an n⁺-type buffer region has to be formed using ion implantation in the diffused wafer 150 when the diffused wafer 150 is used in an igniter. The n⁻-type drift region 153 is a portion of the diffused wafer 150 other than the n⁺-type diffusion layer 152. When the n⁺-type buffer region is formed in the diffused wafer 150, the number of the manufacturing steps increases whereby the cost increases. In addition, it is difficult to form the n⁺-type buffer region to have a high impurity concentration at a depth position of several 10 μm from the front surface of the diffused wafer 150. In manufacturing the IGBT 111 and the MOSFET 112d (see FIG. 14) using the diffused wafer 150, a technique has to be devised to achieve predetermined specifications.

When the diffused wafer 150 is used, it is advantageous to form the p⁺-type diffusion layer 152 that becomes the p⁺-type collector layer, to have a thickness equal to that in the product. Back-grinding to reduce the thickness of the wafer is therefore not conducted during the manufacturing process. Therefore, from the start of the manufacturing process, the thickness of the diffused wafer 150 is thin like the thickness of the product and is, for example, about 200 μm to suppress the occurrence of warpage during the manufacturing process and the occurrence of breakage, -chipping, and the like of the wafer during transportation of the wafer. When the diffused wafer 150 is used, the thickness of the n⁻-type drift region 153 is about 100 μm. The withstand capability against surge voltage (hereinafter, referred to as “surge withstanding capability”) is however reduced when the thickness of the n⁻-type drift region 153 is increased.

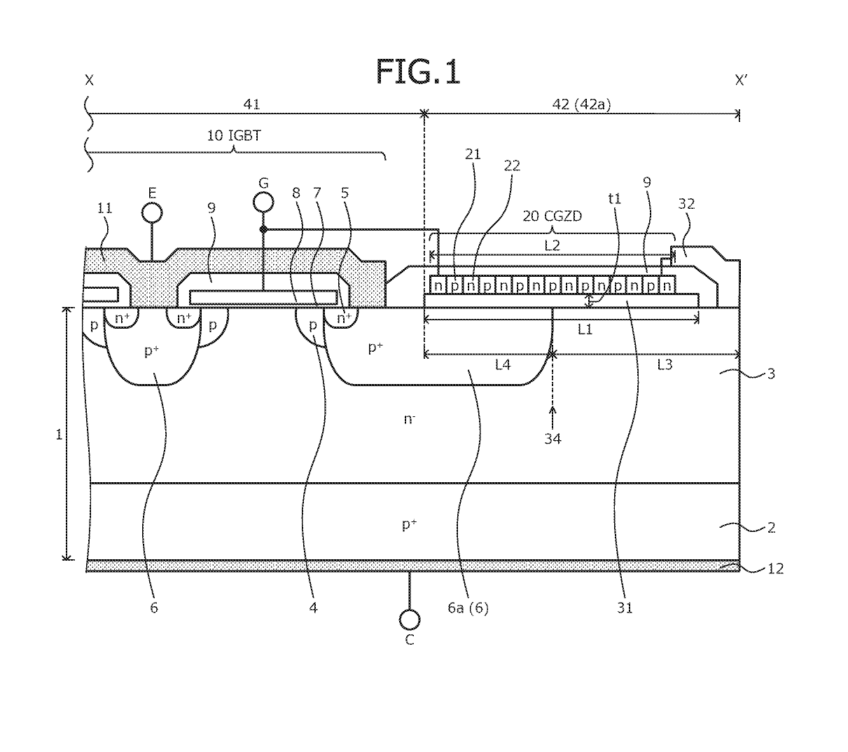

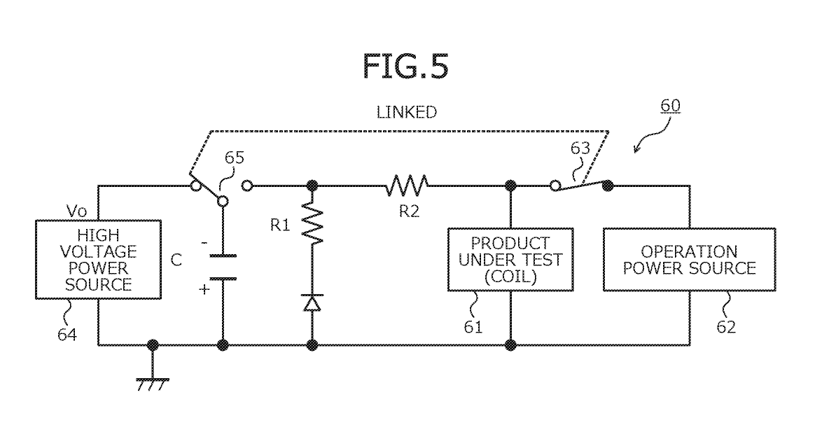

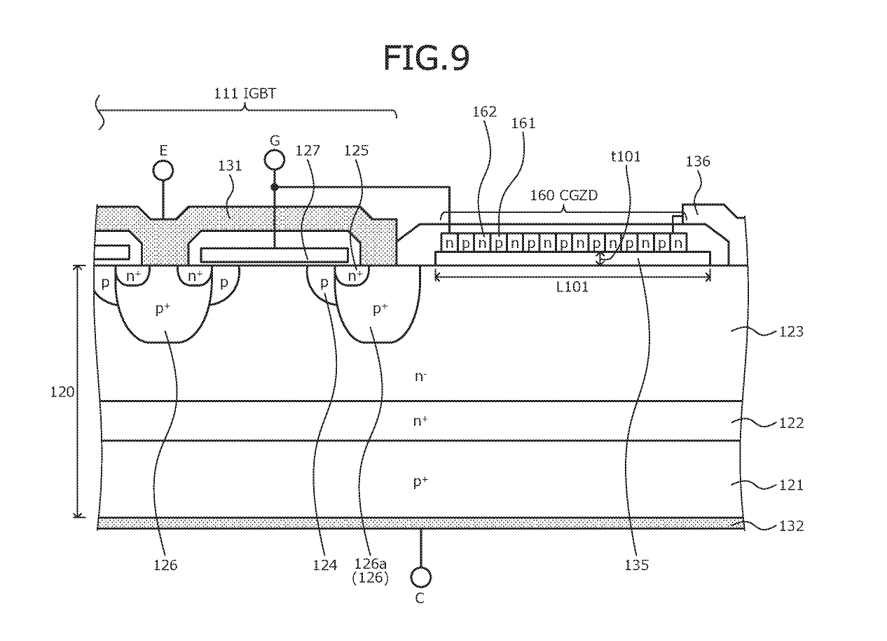

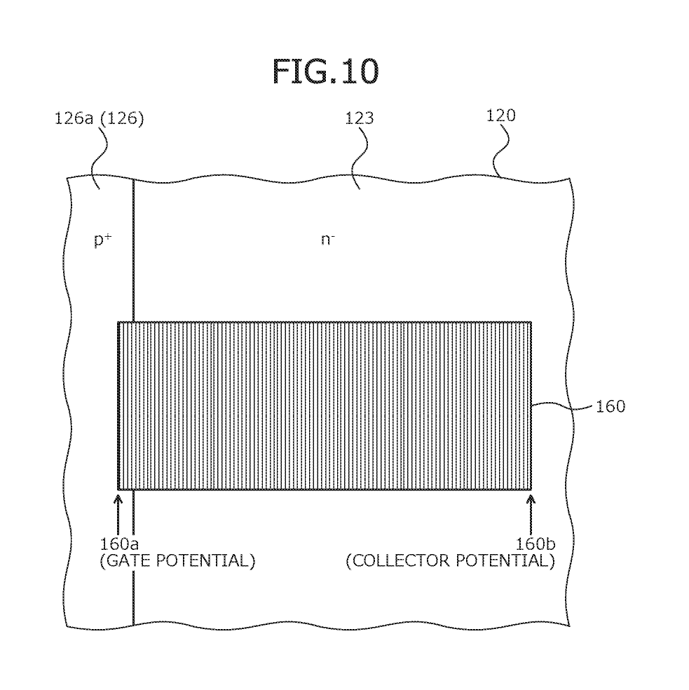

Reduction of the surge withstanding capability by an increase of the thickness of the n⁻-type drift region will be described taking an example of an igniter having a configuration in which an IGBT and a Zener diode (ZD) that protects the IGBT from surge voltage are arranged on the same single semiconductor substrate. FIG. 9 is a cross-sectional view of another example of a structure of main portions of a conventional igniter. FIG. 9 corresponds to FIG. 1 of each of Japanese Laid-Open Patent Publication No. H08-088354 and the International Patent Publication WO 2014/142331, and FIG. 5 of Japanese Patent Publication No. 5194359. FIG. 10 is a plan diagram of the planar layout of the Zener diode of FIG. 9. A planar layout refers to a planar shape, an arrangement and configuration of the components as viewed from the front surface of the semiconductor substrate 120. The igniter depicted in FIG. 9 includes the IGBT 111 and the Zener diode (denoted by “CGZD” in FIG. 9) 160 on the same semiconductor substrate 120. The configuration of the IGBT 111 is same as that depicted in FIG. 14.

The Zener diode 160 is provided through a field oxide film 135 on the front surface of the semiconductor substrate 120 on the outer side (the chip edge side) of the IGBT 111. An inner side (the IGBT 111 side) end portion 160a of the Zener diode 160 is electrically connected to a gate terminal G of the IGBT 111, and an outer side end portion 160b thereof is electrically connected to a stopper electrode 136 that is at a collector potential of the IGBT 111. The inner side end portion 160a of the Zener diode 160 is positioned at substantially a same position as a boundary between an outer side end portion of the p⁺-type region 126 (hereinafter, referred to as “outermost p⁺-type region 126a”) arranged outermost and the n⁻-type drift region 123 (FIG. 10). Reference numerals “161” and “162” respectively denote a p-type polysilicon (poly-Si) layer and an n-type polysilicon layer that constitute the Zener diode 160.

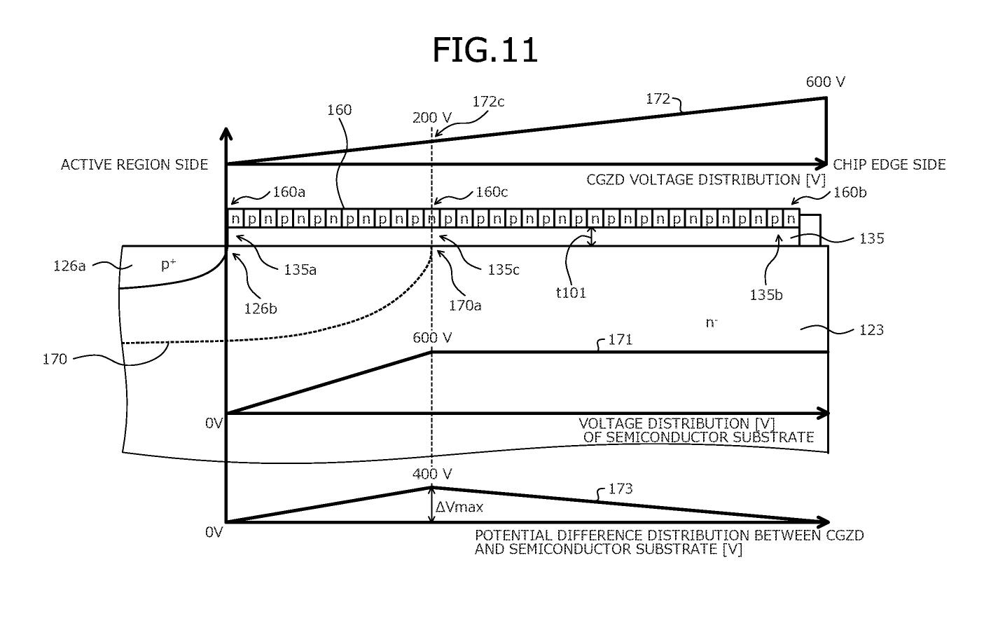

The Zener diode 160 causes a current to flow from the collector toward the emitter of the IGBT 111 to energize the IGBT 111 and thereby protects the IGBT 111 from surge voltage when surge voltage is generated at the collector terminal C of the IGBT 111 in a case where the IGBT is turned off. It is assumed that surge voltage steeper than voltage during operation of the Zener diode 160 such as, for example, an electro-static discharge (ESD) is generated at the collector terminal C of the IGBT 111 when the IGBT 111 is turned off in the igniter having the above configuration. In this case, a depletion layer spreads from a pn-junction formed by the p⁺-type region 126 and the n⁻-type drift region 123, to the n⁻-type drift region 123 due to the energization of the IGBT 111 (see FIG. 11 described later). Therefore, design conditions differ based on the difference in the configuration of the semiconductor substrate 120.

When the epitaxial wafer 140 (see FIG. 8A) is used as the semiconductor substrate 120 and the specific resistance and the thickness of the n⁻-type drift region 123 are, for example, 20 Ω·cm and 50 μm, respectively, and the breakdown voltage of the n⁻-type drift region 123 is about 500 V. This breakdown voltage is the voltage between the collector and the emitter generated when the depletion layer spreading from the pn-junction between the p⁺-type region 126 and the n⁻-type drift region 123 to the n⁻-type drift region 123 reaches the n⁺-type buffer region 122 to cause punching-through. Although surge current flows through the IGBT 111 from a collector side thereof to an emitter side thereof when the depletion layer reaches the n⁺-type buffer region 122, the predetermined surge withstanding capability may be ensured by properly setting the specific resistance and the thickness of the n⁺-type buffer region 122.

On the other hand, when the diffused wafer 150 is used as the semiconductor substrate 120 (see FIG. 8B), a non-punch-through type is established in which the p⁺-type collector region 121 and the n⁻-type drift region 123 are formed adjacent to each other. When the depletion layer spreading from the pn-junction formed between the p⁺-type region 126 and the n⁻-type drift region 123 to the n⁻-type drift region 123 reaches the p⁺-type collector region 121, large surge current may flow compared to that in a case where the n⁺-type buffer region is present and the IGBT 111 may be destroyed. Therefore, the specific resistance and the thickness of the n⁻-type drift region 123 have to be set such that the depletion layer spreading from the front surface side of the substrate does not reach the p⁺-type collector region 121 when surge voltage is generated. The thickness of the n⁻-type drift region 123 is set to be large to suppress the occurrence of warpage, breakage, and chipping of the wafer during the manufacturing process as described above.

When the specific resistance and the thickness of the n⁻-type drift region 123 are set to be, for example, 20 Ω·cm and 80 μm, respectively, the breakdown voltage of the n⁻-type drift region 123 in a case where surge voltage is generated is 800 V. A configuration is established in which the IGBT 111 is not destroyed until the voltage between the collector and the emitter reaches 800 V when surge voltage is generated thereby improving the surge withstanding capability. However, when the breakdown voltage of the n⁻-type drift region 123 is increased, the breakdown voltage of an insulation isolation structure has to be increased between the Zener diode 160 and the semiconductor substrate 120 commensurate with the breakdown voltage of the n⁻-type drift region 123. The insulation isolation structure includes the field oxide film 135 arranged between the Zener diode 160 and the semiconductor substrate 120. The breakdown voltage of the field oxide film 135 is determined according to a width L101 and a thickness t101 of the field oxide film 135.

For example, taking the reliability (the security margin) into consideration, the thickness t101 of the field oxide film 135 is set to be equal to or larger than a thickness capable of enduring at least the potential difference generated between the Zener diode 160 and the semiconductor substrate 120 when surge voltage is generated. FIG. 11 is a characteristics diagram of distribution of the potential difference between the Zener diode and the semiconductor substrate of FIG. 9. Reference numerals “171” and “172” respectively denote voltage distributions of the n⁻-type drift region 123 and the Zener diode 160. A reference numeral “173” denotes distribution of the potential difference between the Zener diode 160 and the semiconductor substrate 120, and this corresponds to the voltage distribution of the field oxide film 135. For example, it is assumed that the voltage between the collector and the emitter applied to the IGBT 111 when surge voltage is generated is 600 V.

As depicted in FIG. 11, when surge voltage is generated, the depletion layer 170 spreads from the pn-junction between the p⁺-type region 126 and the n⁻-type drift region 123 toward the outer side. The voltage concentration point (the maximal value of the voltage distribution 171) of the n⁻-type drift region 123 moves outward to be at an end portion position 170a of the depletion layer 170. For example, when the surge voltage is generated, voltage is applied to the n⁻-type drift region 123 and exhibits the distribution 171 that linearly increases by a predetermined slope from a position 126b of the emitter potential (=0 V) of the IGBT 111 toward the outer side, has a maximal value of 600 V at the end portion position 170a of the depletion layer 170, and that maintains the maximal value up to the chip edge portion. The position 126b of the emitter potential of the IGBT 111 is the outer side end portion position of the outermost p⁺-type region 126a.

On the other hand, the Zener diode 160 has the inner side end portion 160a at the gate potential of the IGBT 111 and the outer side end portion 160b at the collector potential (the substrate potential) of the IGBT 111. When surge voltage is generated, voltage is applied to the Zener diode 160 and exhibits the distribution 172 that linearly increases by a predetermined slope from the inner side end portion 160a of the Zener diode 160 toward the outer side and has a maximal value of 600 V at the outer side end portion 160b. The voltage applied to the Zener diode is lower than 600 V (is set to be, for example, 200 V in FIG. 11) in a portion 172c that faces the voltage concentration point of the n⁻-type drift layer 123 (the end portion position 170a of the depletion layer 170) in the depth direction, and the maximal potential difference ΔVmax (=600 V−200 V=400 V) is generated between the portion 172c and the n⁻-type drift layer 123.

The Zener diode 160 is arranged at a position that is on the outer side of the outermost p⁺-type region 126a and does not to face the outermost p⁺-type region 126a in the depth direction. The inner side end portion 160a of the Zener diode 160 is positioned at the same position as that of the boundary between the outer side end portion of the outermost p⁺-type region 126a and the n⁻-type drift region 123 (see FIG. 10) or at a position on the outer side of this boundary. The position at which the voltage distribution 172 of the Zener diode 160 becomes minimal is same as the position at which the voltage distribution 171 of the n⁻-type drift region 123 becomes minimal, or is on the outer side of the position at which the voltage distribution 171 of the n⁻-type drift region 123 becomes minimal. FIG. 11 depicts a case where the position at which the voltage distribution 172 of the Zener diode 160 becomes minimal and the position at which the voltage distribution 171 of the n⁻-type drift region 123 becomes minimal are the same position.

Voltage is applied to the field oxide film 135, exhibiting the distribution 173 and potential equal to the potential difference ΔV occurring between the Zener diode 160 and the n⁻-type drift region 123. For example, the voltage applied to the field oxide film 135 has a minimal value of 0 V at a position 135a facing the inner side end portion 160a of the Zener diode 160 in the depth direction. The voltage applied to the field oxide film 135 linearly increases by a predetermined slope from the position 135a, and has a minimal value of 0 V toward the outer side and a maximal value (ΔVmax=400 V) at a position 135c facing the end portion position 170a of the depletion layer 170 in the depth direction. In addition, the voltage applied to the field oxide film 135 linearly decreases by a predetermined slope from the position 135c, and has a maximal value of 400 V toward the outer side and a minimal value of 0 V at a position 135b facing the outer side end portion 160b of the Zener diode 160 in the depth direction (near the chip edge portion).

The maximal voltage applied to the field oxide film 135 is the maximal potential difference ΔVmax between the Zener diode 160 and the n⁻-type drift region 123, and the voltage distribution 173 of the field oxide film 135 has a substantially triangle shape whose vertex is the position of the maximal voltage. As described, when the diffused wafer 150 (see FIG. 8B) is used as the semiconductor substrate 120, because the breakdown voltage of the n⁻-type drift region 123 is increased by the increased thickness of the n⁻-type drift region 123, the maximal potential difference ΔVmax between the Zener diode 160 and the n⁻-type drift region 123 may also be increased. Therefore, the breakdown voltage of the field oxide film 135 has to be increased by increasing the thickness t101 of the field oxide film 135 by the amount corresponding to the increase of the breakdown voltage of the n⁻-type drift region 123.

It is assumed that, for example, the field oxide film 135 may endure a surge voltage of 400 V with the thickness t101 of 400 nm. In this case, assuming that the maximal voltage applied to the field oxide film 135 is 600 V due to the increased thickness of the n⁻-type drift region 123, the thickness t101 of the field oxide film 135 has to be equal to or larger than 600 nm. In this manner, the breakdown voltage of the field oxide film 135 may be improved up to a certain range by increasing the thickness t101 of the field oxide film 135. New problems however arise such as an increase of the number of the manufacturing steps, a longer time period to form the field oxide film 135, a decrease in the yield rate of non-defective products caused by exposing the semiconductor wafer to a high temperature for a long period, and an adverse effect in achieving size reductions due to increased unevenness of the surface of the semiconductor wafer.

A countermeasure is generally taken to reduce the operating resistance by increasing the length of the pn-junction of the Zener diode 160 or by reducing the resistance value of a series resistor connected between the driver circuit and the gate electrode. With this countermeasure, however, the reduction of the potential difference generated between the Zener diode 160 and the n⁻-type drift region 123 is limited because the difference in the voltage variation rate between the inside of the silicon portion (the n⁻-type drift region 123) and the inside of the polysilicon portion (the Zener diode 160) saturates to a certain extent. The increased length of the pn-junction of the Zener diode 160 causes another problem in that the area that the Zener diode 160 occupies increases.

According to the present invention, however, the IGBT (the semiconductor element) and the diode to protect the IGBT may be configured in a state where the breakdown voltage of the field oxide film (the oxide film) electrically insulating the IGBT and the diode from each other is maintained. According to the present invention, a diffused wafer lower in cost than an epitaxial wafer may be used because the IGBT may be configured to be a non-punch-through type IGBT.

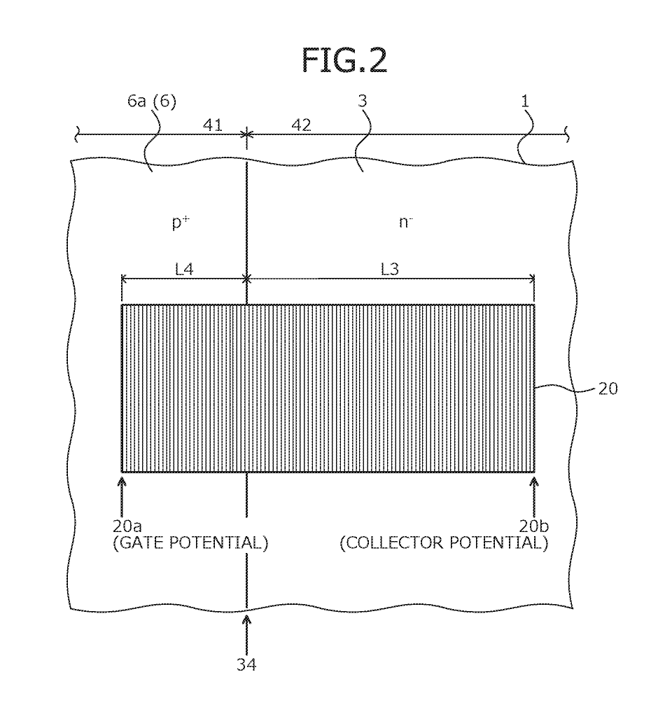

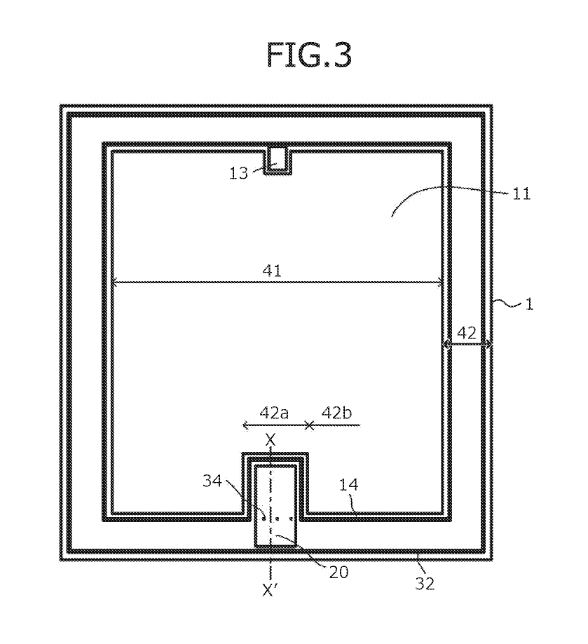

A structure of a semiconductor device according to an embodiment will be described. FIG. 1 is a cross-sectional view of a structure of the semiconductor device according to the embodiment, taken along a cutting line X-X′ of FIG. 3. FIG. 2 is an enlarged plan diagram of a Zener diode 20 of FIG. 3. FIG. 3 is a plan diagram of a planar layout of the semiconductor device according to the embodiment. In FIG. 3, a gate wire 14 and a stopper electrode 32 are indicated by solid lines. The semiconductor device according to the embodiment and depicted in FIGS. 1 to 3 is produced (manufactured) using, for example, a diffused wafer that includes a p⁺-type diffusion layer (second semiconductor layer of a second conductivity type) 2 that is formed by diffusing, for example, boron (B) in a surface layer of a main surface (rear surface) of an n⁻-type starting wafer 1.

An n⁻-type semiconductor substrate (semiconductor chip, hereinafter, referred to as “semiconductor substrate 1”) that is one of plural chips formed by cutting (dicing) the diffused wafer into individual chips will be described. The semiconductor substrate 1 has a planar shape that is, for example, a substantially rectangular shape. An IGBT 10 and the Zener diode (a CGZD) 20 are provided on the same semiconductor substrate 1. The IGBT 10 is provided in an active region 41. A p⁺-type diffusion layer 2 functions as a p⁺-type collector region. An n⁻-type semiconductor layer (first semiconductor layer of a first conductivity type) that is a portion of the semiconductor substrate 1 other than the p⁺-type diffusion layer 2 is an n⁻-type drift region 3. The IGBT 10 is a non-punch-through type IGBT that includes the p⁺-type collector region and the n⁻-type drift region 3 that are adjacent to each other, and no n⁺-type buffer region is provided.

A thickness of the p⁺-type diffusion layer 2 may be preferably, for example, about 100 μm or greater. The reason for this is as follows. When the semiconductor substrate 1 is soldered to a circuit pattern (copper foil) on an insulated substrate during the manufacturing of a product, the solder adheres to the side face of the substrate (cut face). In this case, adhesion of the solder to the end portion of a pn-junction between the p⁺-type diffusion layer 2 and the n⁻-type drift region 3 may be prevented. A thickness of the n⁻-type drift region 3 has to be at least several 10 μm or greater to ensure a predetermined breakdown voltage (for example, about 300 V or higher) and is, for example, about 40 μm to about 200 μm.

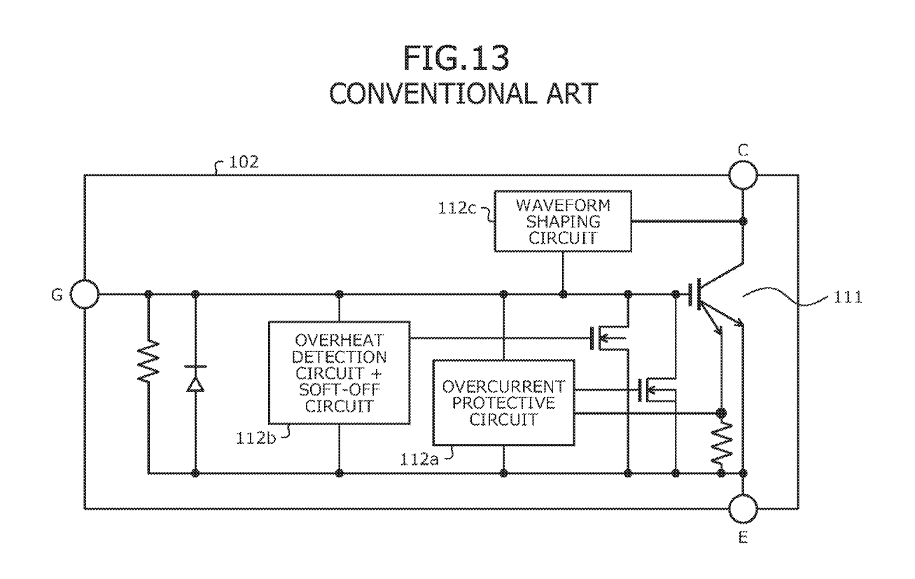

The thickness of the n⁻-type drift region 3 may be preferably about 100 μm or greater. The reason for this is that, preferably, a thickness of the semiconductor substrate 1 is about 200 μm or greater for handling of the diffused wafer during the manufacturing process when, for example, a diffused wafer of 5 inches is used. A resistance value of the n⁻-type drift region 3 may be preferably about 1Ω to about 100Ω whereby the breakdown voltage of the IGBT 10 may be ensured and the breakdown voltage of a horizontal MOSFET (see FIG. 13) constituting a control circuit/protective circuit of the IGBT 10 may be ensured.

The Zener diode 20 is provided in an edge termination region 42. The Zener diode 20 has a function of clamping excessive surge voltage generated at a collector terminal of the IGBT 10 and thereby protects the IGBT 10 from the surge voltage. The active region 41 is a region through which current flows during an on-state. The edge termination region 42 is a region between the active region 41 and a chip edge portion, surrounds a periphery of the active region 41, and mitigates the electric field on a front surface side of the substrate (the front surface of the semiconductor substrate 1) in the n⁻-type drift region 3 to maintain the breakdown voltage.

A portion (hereinafter, referred to as “first portion”) 42a of the edge termination region 42 in which the Zener diode 20 is provided has a planar shape that protrudes inwardly (toward the active region 41) to have convex shape having a length L2 of the Zener diode 20 and a width larger than that of another portion (hereinafter, referred to as “second portion”) 42b (FIG. 3). The length 2L of the Zener diode 20 is a length in a direction from the inner side toward the outer side.

In the active region 41, a p-type base region 4 is selectively provided in the surface layer of the other main surface (the front surface: the surface on the n⁻-type drift region 3 side) of the semiconductor substrate 1. In the p-type base region (first semiconductor region) 4, an n⁺-type emitter region (second semiconductor region) 5 is selectively provided. A p⁺-type region (third semiconductor region) 6 is provided that penetrates the p-type base region 4 in the depth direction to reach the n⁻-type drift region 3. The p⁺-type region 6 is in contact with the n⁺-type emitter region 5 and functions as a p⁺-type contact region. The p⁺-type region 6 may be formed preferably before the formation of a field oxide film 31 described later.

The p⁺-type region 6 may have low resistance, preferably. For example, the dose amount of the ion implantation used when the p⁺-type region 6 is formed is, for example, may be preferably 5×10¹⁴/cm²or more. The reason for this is that, for example, in the p⁺-type region 6 arranged in the outermost side (hereinafter, referred to as “outermost p⁺-type region 6a”), when surge voltage is generated, a large current instantaneously flows through a portion that faces the Zener diode 20 in the depth direction described later.

The position of the outer side end portion of the outermost p⁺-type region 6a is set such that, when a surge voltage is generated or when the IGBT 10 is turned off, the depletion layer extending from the pn-junction between the outermost p⁺-type region 6a and the n⁻-type drift region 3 does not reach the stopper electrode 32. The reason for this is that, when the depletion layer reaches the stopper electrode 32, the collector and the emitter of the IGBT 10 are short-circuited and the IGBT 10 does not function.

In the second portion 42b of the edge termination region 42, the outermost p⁺-type region 6a is terminated at the boundary between the active region 41 and the edge termination region 42. In the first portion 42a of the edge termination region 42, the outermost p⁺-type region 6a extends from the active region 41 to the edge termination region 42. For example, when the outermost p⁺-type region 6a is extended outward in the first portion 42a of the edge termination region 42 as follows, the depletion layer extending from the pn-junction between the n⁻-type drift region 3 and the outermost p⁺-type region 6a does not reach the stopper electrode 32 and increases of the chip area may be prevented.

In the second portion 42b of the edge termination region 42, the width of the second portion 42b of the edge termination region 42 is set to be a width by which the depletion layer extending from the pn-junction between the outermost p⁺-type region 6a and the n⁻-type drift region 3 does not reach the stopper electrode 32. In the first portion 42a of the edge termination region 42, the outermost p⁺-type region 6a may be extended to a position 34 so that a length L3 (length along a direction parallel to the front surface of the substrate) from the outer side end portion (position 34) of the outermost p⁺-type region 6a to the chip edge portion is at least the width of the second portion 42b of the edge termination region 42.

On the surface of a portion of the p-type base region 4 between the n⁻-type drift region 3 and the n⁺-type emitter region 5, a gate electrode 8 is provided via a gate insulating film 7. The p-type base region 4, the n⁺-type emitter region 5, the p⁺-type region 6, the gate insulating film 7, and the gate electrode 8 constitute a MOS gate of a planar gate structure. An emitter electrode (first electrode) 11 is in contact with the n⁺-type emitter region 5 and the p⁺-type region 6, and is electrically insulated from the gate electrode 8. A collector electrode (second electrode) 12 is provided on the entire rear surface (surface on the p⁺-type diffusion layer 2 side) of the semiconductor substrate 1.

In the edge termination region 12, the Zener diode 20 is provided on the front surface of the semiconductor substrate 1, via the field oxide film 31. The Zener diode 20 includes a p-type polysilicon (poly-Si) layer 21 becoming a p-type anode region and an n-type polysilicon layer 22 becoming an n-type anode region alternately and repeatedly arranged from the inner side toward the outer side (chip edge side) along a direction parallel to the front surface of the substrate. Both ends of the Zener diode 20 are n-type polysilicon layers 22. Plural diodes each formed by a pn-junction of the p-type polysilicon layer 21 and the n-type polysilicon layer 22 are connected to each other in series and at least one of the diodes is reversely connected in series thereto.

One end portion of the Zener diode 20 (an inner side end portion 20a) is electrically connected to the gate electrode 8 of the IGBT 10 via the gate electrode 14, and the other end portion (an outer side end portion 20b) is electrically connected to the stopper electrode 32 at the collector potential (the potential of the substrate). The gate wire 14 is a gate runner (metal wire) that is coupled to the gate electrode 8 and the gate pad 13. The Zener diode 20 faces the outermost p⁺-type region 6a across the field oxide film 31 in the depth direction.

For example, a portion of the Zener diode 20 having a length equal to or longer than about ⅓ of the length L2 from the inner side end portion 20a of the Zener diode 20 faces the outermost p⁺-type region 6a in the depth direction across the field oxide film 31 (FIG. 2). For example, when the breakdown voltage of the field oxide film 31 is 400 V and the specific resistance of the n⁻-type drift region 3 is 20 Ω·cm, a width L4 of the portion of the Zener diode 20 facing the outermost p⁺-type region 6a in the depth direction across the field oxide film 31, on the inner side end portion side (the side of the gate potential) of the Zener diode 20 may be about 50 μm to about 210 μm.

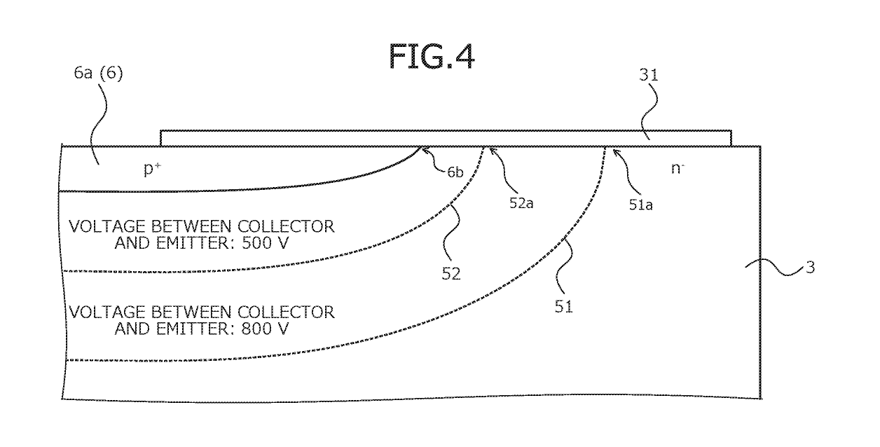

The position of the emitter potential (=0 V) of the IGBT 10 is the position of the outer side end portion of the outermost p⁺-type region 6a. In the first portion 42a of the edge termination region 42, the position of the emitter potential of the IGBT 10 may therefore be positioned on the outer side of the inner side end portion 20a of the Zener diode 20. End portion positions 51a and 52a (see FIG. 4) of depletion layers 51 and 52 from the pn-junction between the p⁺-type region 6 and the n⁻-type drift region 3 to be the voltage concentration point of the n⁻-type drift region 3, are positioned on the outer side of those of the conventional structure (see FIG. 11).

A thickness [nm] t1 of the field oxide film 31 is a value that is at least 10 times the value of the voltage applied to both ends of the field oxide film 31 (i.e., the insulation breakdown voltage of the field oxide film 31). When the insulation breakdown voltage of the field oxide film 31 is 400 V, the thickness of the field oxide film 31 is at least about 400 nm. The thickness of the field oxide film 31 may be about a 20-fold thickness [nm] of that for the voltage applied to both ends of the field oxide film 31, and may be increased to be, for example, about 1,000 nm to about 3,000 nm.

The field oxide film 31 may be preferably formed as early as possible in the manufacturing process. The reason for this is that, when the field oxide film 31 is formed, as a result of the heat treatment applied to the semiconductor substrate 1, protrusions and recesses are produced on the front surface of the semiconductor substrate 1. The Zener diode 20 is covered by an interlayer insulating film 9. The stopper electrode 32 is in contact with the front surface of the semiconductor substrate 1 near the chip edge portion, and is electrically connected to the n⁻-type drift region 3. The stopper electrode 32 may be electrically connected to the n⁻-type drift region 3 through an n-type channel stopper region not depicted.

FIG. 4 is an explanatory diagram of a state of the depletion layer in the edge termination region of FIG. 1. Because the IGBT 10 is a non-punch-through type IGBT as described above, the thickness of the n⁻-type drift region 3 is thicker than that of the punch through type IGBT having an n⁺-type buffer region. The breakdown voltage of the n⁻-type drift region 3 is increased by an amount corresponding to the increase of the thickness of the n⁻-type drift region 3. For example, as depicted in FIG. 4, when the voltage between the collector and the emitter is 800 V, the depletion layer 51 that extends from the pn-junction between the outermost p⁺-type region 6a and the n⁻-type drift region 3 extends on the outer side of the depletion layer 52 formed when the voltage between the collector and the emitter is 600 V.

The surge withstanding capability is reduced by an amount corresponding to the increase of the thickness of the n⁻-type drift region 3. Therefore, a width L1 of the field oxide film 31 has to be increased by the amount corresponding to the increase of the thickness of the n⁻-type drift region 3. The width L1 of the field oxide film 31 is the length between the inner side end portion and the outer side end portion of the field oxide film 31. For example, in the conventional structure, when the breakdown voltage of the n⁻-type drift region 123 is 500 V, it is assumed that the width L101 of the field oxide film 135 is 80 μm (see FIG. 9). In this case, in the present invention, when the breakdown voltage of the n⁻-type drift region 3 is increased to 800 V, the width L1 of the field oxide film 31 is set to 128 μm or more (=80 μm×800 V/500 V).

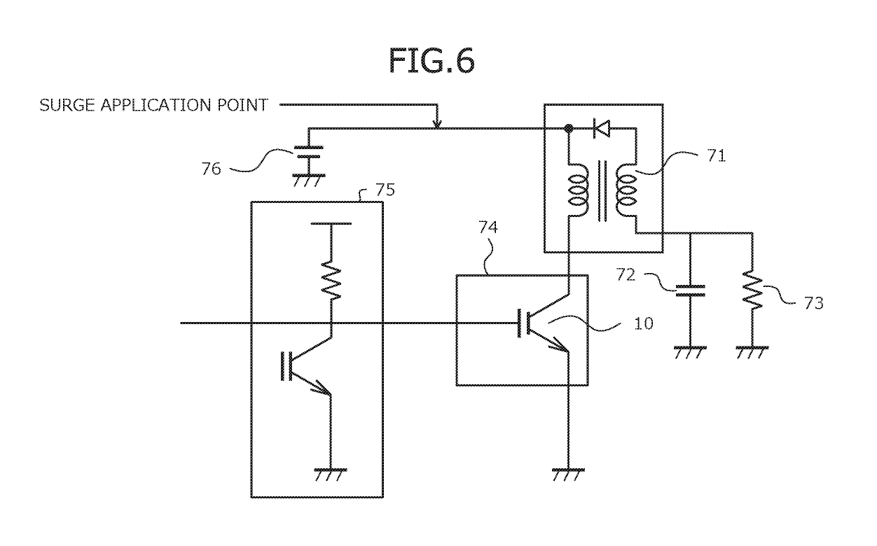

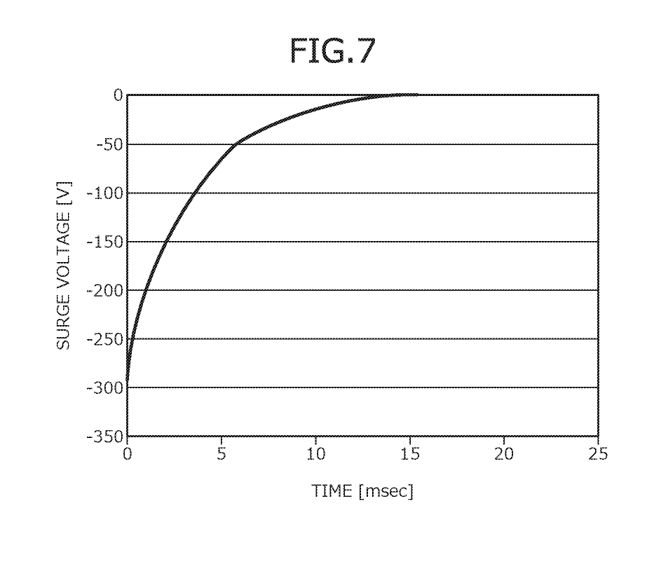

Surge voltage may be generated between the collector and the emitter of the IGBT 10, and the withstand capability thereof is generally evaluated by a field decay test. FIG. 5 is a circuit diagram of a surge voltage generating circuit that is used in the field decay test. FIG. 6 is an explanatory diagram of a surge voltage application point of an internal combustion engine ignition in the field decay test. FIG. 7 is a characteristics diagram of a surge voltage waveform applied in the field decay test. The field decay test is a test to measure the withstand capability of an electronic device such as an igniter against the various types of negative surge voltage such as a field decay noise discharged from a field coil of an alternator (hereinafter, referred to as “field decay noise withstand capability”).

The surge voltage generating circuit 60 depicted in FIG. 5 is a field decay testing apparatus that applies negative surge voltage to a product 61 under test. The product 61 under test operates when a first switch 63 that is arranged between the product 61 under test and a power source 62 is turned on to operate the product under test. A second switch 65 turned on or off associated with the turning on or off of the first switch 63 is arranged between the product 61 under test and a high voltage power source 64. A predetermined voltage of, for example, about +30 V to about −350 V is applied to the product 61 under test from the high voltage power source 64 when the second switch 65 is turned on (see FIG. 7). For example, when solder adheres to the end portion of the pn-junction between the p⁺-type diffusion layer 2 and the n⁻-type drift region 3 in the IGBT 10, the product 61 under test is destroyed at a negative voltage of about −350 V.

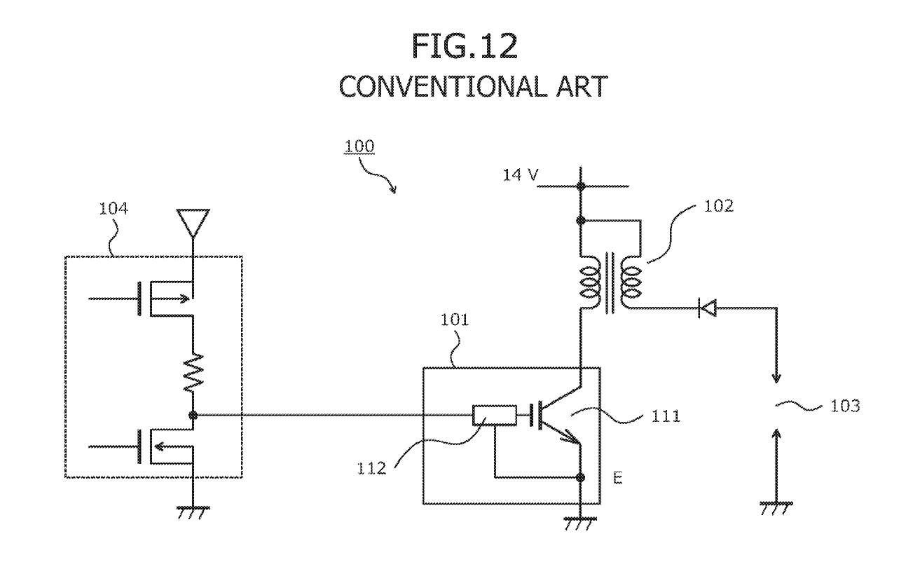

The product 61 under test is the internal combustion engine ignition depicted in FIG. 6. The internal combustion engine ignition depicted in FIG. 6 is a general internal combustion engine ignition (see FIG. 12). An ignition coil 71 corresponds to the ignition coil 102 in FIG. 12, and a capacitor 72 and a resistor 73 correspond to the spark plug 103 in FIG. 12. The IGBT 10 is a switch that causes the low voltage current flowing through the primary coil of the ignition coil 71 to flow or stop, and constitutes an igniter 74. An ECU 75 corresponds to the ECU 104 in FIG. 12. The predetermined voltage is applied by the surge voltage generating circuit 60, between the ignition coil 71 and a battery 76 that supplies a current to the ignition coil 71 (surge application point).

A positive voltage by which the collector potential is a positive potential relative to the emitter potential is usually applied between the collector and the emitter of the IGBT 10 while a negative voltage (negative surge voltage) by which the collector potential is a negative potential relative to the emitter potential is applied by the surge voltage generating circuit 60. As a result, for the IGBT 10 constituting the igniter 74, current (hereinafter, referred to as “negative surge current”) flows from the region at the emitter potential on the front surface of the substrate (the n⁺-type emitter region 5, the p-type base region 4, and the p⁺-type region 6) toward the collector electrode 12 through the n⁻-type drift region 3 and the p⁺-type diffusion layer 2. In this case, the amount of the generated heat in the IGBT 10 becomes maximal in the pn-junction portion between the p⁺-type diffusion layer 2 and the n⁻-type drift region 3.

When the negative voltage applied by the surge voltage generating circuit 60 is higher than the reverse direction breakdown voltage obtained at the pn-junction between the p⁺-type diffusion layer 2 and the n⁻-type drift region 3, breakdown occurs in the pn-junction portion and the negative surge current flows therethrough. In comparing cases for reverse direction breakdown voltage of 30 V and for reverse direction breakdown voltage of 50 V, the IGBT 10 having a chip area of, for example, 20 mm² exhibits a field decay noise withstand capability that is substantially in proportion to the reverse direction breakdown voltage. This is because the operating resistance of the IGBT 10 is low after the breakdown occurs at the pn-junction between the p⁺-type region 6 and the n⁻-type drift region 3 and therefore, the negative surge current at a substantially equal level flows regardless of the difference in the reverse direction breakdown voltage. The reverse direction breakdown voltage determined based on the pn-junction between the p⁺-type diffusion layer 2 and the n⁻-type drift region 3 in the IGBT 10 is determined according to the specific resistance of the n⁻-type drift region 3 to be high when the specific resistance of the p⁺-type diffusion layer 2 is sufficiently low, and is determined according to the specific resistance of the p⁺-type diffusion layer 2 to be low when the specific resistance of the p⁺-type diffusion layer 2 is high. The reverse direction breakdown voltage of the IGBT 10 is, for example, substantially equal to or higher than that of the conventional structure (about 28 V) and may be, for example, about 700 V.

The non-punch-through type IGBT 10 manufactured using the diffused wafer has no n⁺-type buffer region, different from the punch through type IGBT manufactured using the epitaxial wafer. In the non-punch-through type IGBT 10, to ensure the breakdown voltage of the n⁻-type drift region 3, the resistance value of the n⁻-type drift region 3 cannot be reduced to be substantially equal to that of the n⁺-type buffer region of the punch through type IGBT. Usually, the resistance value of the n⁻-type drift region is 100-fold higher than the resistance value of the n⁺-type buffer region and therefore, in the non-punch-through type IGBT 10 of the present invention, the reverse direction breakdown voltage determined based on the pn-junction between the p⁺-type diffusion region 2 and the n⁻-type drift region 3 is on the order of several 100 V. In general, the field decay noise withstand capability of the non-punch-through type IGBT suffices to be about 60 V and therefore, the IGBT 10 of the present invention may sufficiently obtain the field decay noise withstand capability when the IGBT 10 has a typical chip size.

As described above, according to the embodiment, the voltage concentration point in the n⁻-type drift region occurring when negative surge voltage is generated may be positioned farther outward than the inner side end portion of the Zener diode (the end portion of the gate potential side) by arranging the Zener diode to face the outermost p⁺-type region of the IGBT, across the field oxide film in the depth direction. Therefore, the potential difference that is generated between the Zener diode and the semiconductor substrate when the negative surge voltage is generated may be reduced. In other words, the voltage applied to the field oxide film may be reduced. Therefore, by manufacturing the non-punch-through type IGBT using the diffused wafer and not the epitaxial wafer, even when the thickness of the n⁻-type drift region of the IGBT is increased, no design change for the thickness of the field oxide film is necessary.

Because no design change is necessary for the thickness of the field oxide film as described above, the thickness of the field oxide film may be maintained to be substantially equal to that of the punch through type IGBT manufactured using the epitaxial wafer. Therefore, no recipe for the manufacturing process to form the field oxide film needs to newly be set for each product, and the existing manufacturing line may be used. There is no increase in crystal faults and no test to check the crystal faults of the field oxide film needs to be conducted due to the longer time period for the formation of the field oxide film (the heat treatment). Decreases in the non-defective product yield due to the increased thickness of the field oxide film may be avoided and increases in the cost associated with the formation of the field oxide film may be prevented.

According to the embodiment, the diffused wafer is inexpensive and the material cost (the cost of the semiconductor crystal) may be reduced to, for example, about ½ of that of the epitaxial wafer by using the diffused wafer whereby the product cost may be reduced. For example, since the ratio of the semiconductor crystal cost (the material cost of the semiconductor substrate) in an integrated circuit (IC) chip for the igniter use is high, about 30% or 40%, and the present invention is useful. According to the embodiment, because the non-punch-through type IGBT is manufactured using the diffused wafer, measures for the FZ wafer such ion implantation to form the n⁺-type buffer region and a structure to prevent any adverse effects caused by the solder adhering to the side face of the chip are unnecessary. The cost of the manufacturing process may be reduced.

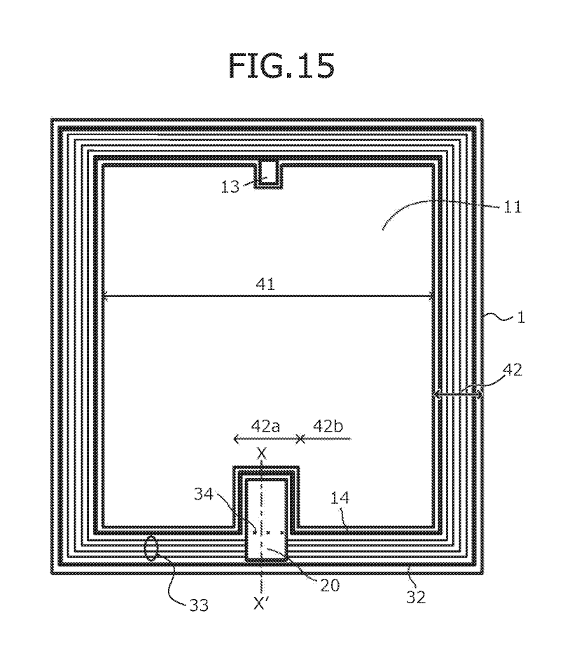

Another example of the semiconductor device according to the embodiment will be described. FIG. 15 is a plan diagram of the planar layout of another example of the semiconductor device according to the embodiment. The semiconductor device according to the embodiment depicted in FIG. 15 differs from the semiconductor device according to the embodiment depicted in FIG. 3 in that the edge termination region 42 has p-type guard rings 33 provided therein in a concentric manner surrounding a periphery of the active region 41. The semiconductor device also includes an electrode (not depicted) that is in contact with the p-type guard rings 33. This electrode is not provided in the first portion 42a of the edge termination region 42. FIG. 15 depicts four p-type guard rings 33 although the number thereof is not limited hereto and the number of the p-type guard rings 33 may variously be changed.

In the description above, the present invention is not limited to the embodiments and various changes may be made thereto within a scope not departing from the spirit of the present invention. For example, the width of the first portion of the edge termination region (the portion having the Zener diode arranged therein) may be increased to be larger than that of the second portion by protruding the first portion to be convex inward in the embodiment while the width of the edge termination region may be constant for the overall circumference surrounding the periphery of the active region. Although the embodiment has been described taking an example of a case where the IGBT and the Zener diode are arranged in a single semiconductor substrate, a p⁺-type region at the emitter potential of the IGBT and having an impurity concentration substantially equal to that of the p⁺-type contact region may be provided on the gate potential side of the Zener diode to face the Zener diode in the depth direction sandwiching the field oxide film therebetween, and the IGBT and the Zener diode may each be arranged on semiconductor substrates different from each other. The present invention is further implemented when the conductivity types (the n-type and the p-type) are inversed.

According to the semiconductor device of the present invention, an effect is achieved in that, in a semiconductor device including an IGBT and a diode to protect the IGBT, the breakdown voltage may be maintained while cost reductions may be achieved.

As described above, the semiconductor device according to the present invention is useful for a power semiconductor device used in an igniter of an automobile, or the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor element including:
a first semiconductor layer of a first conductivity type;
a first semiconductor region of a second conductivity type selectively provided in a surface layer of the first semiconductor layer;
a second semiconductor region of the first conductivity type selectively provided in the first semiconductor region;
a third semiconductor region of the second conductivity type selectively provided in the first semiconductor region, the third semiconductor region having an impurity concentration higher than that of the first semiconductor region;
a gate insulating film in contact with a region of the first semiconductor region between the first semiconductor layer and the second semiconductor region;
a gate electrode facing the first semiconductor region across the gate insulating film;
a second semiconductor layer of the second conductivity type provided on a first surface of the first semiconductor layer opposite a second surface of the first semiconductor layer in which the first semiconductor region is provided;
a first electrode in contact with the second semiconductor region and the third semiconductor region; and
a second electrode in contact with the second semiconductor layer of the second conductivity type;
an oxide film provided on the second surface of the first semiconductor layer; and
a diode provided on a surface of the oxide film, the diode having a first end electrically connected to the gate electrode and a second end electrically connected to the second electrode,
wherein the diode is located on the oxide film, a portion of the diode including the first end is positioned opposite the third semiconductor region across the oxide film.

2. The semiconductor device according to claim 1, wherein
one third or more of the diode on a side including the first end faces is positioned opposite the third semiconductor region across the oxide film in a depth direction.

3. The semiconductor device according to claim 1, wherein
a thickness of the second semiconductor layer is 100 μm or more.

4. The semiconductor device according to claim 1, wherein
a thickness of the first semiconductor layer is 100 μm or more.

5. The semiconductor device according to claim 1, wherein
the second semiconductor layer is a diffusion layer provided in a surface layer of a semiconductor substrate of the first conductivity type, and
the first semiconductor layer is a portion of the semiconductor substrate excluding the second semiconductor layer.

6. The semiconductor device according to claim 5, wherein
a thickness of the semiconductor substrate is 200 μm or more.

7. The semiconductor device according to claim 1, wherein
the semiconductor element is provided in an active region,
the diode is provided in a termination region surrounding a periphery of the active region, and
the terminating region is arranged in a layout in which a portion having the diode provided therein protrudes toward the active region.
